(19) United States
(12) Patent Application Publication
(10) Pub. No.: US 2026/0304643 A1
(43) Pub. Date: Oct. 1, 2026

(54) MANUFACTURING METHOD FOR LONG CIRCUIT BOARD AND LONG CIRCUIT BOARD

(71) Applicant: Dingfeng WANG, Shenzhen (CN)

(72) Inventors: Dingfeng WANG, Shenzhen (CN); Hongxin DAI, Tongling (CN); Lei XU, Tongling (CN); Shengqi WANG, Tongling (CN); Wenhong XU, Tongling (CN)

(21) Appl. No.: 19/483,224

(22) PCT Filed: Sep. 13, 2023
(86) PCT No.: PCT/CN2023/118418

§ 371 Date: Nov. 10, 2025

(30) Foreign Application Priority Data
May 10, 2023 (CN) 202310542491.1
May 10, 2023 (CN) 202321180414.8

(51) Int. Cl. H05K 3/36; H05K 1/02; H05K 1/14; H05K 3/00; H05K 3/02; H05K 3/04; H05K 3/40

(52) U.S. Cl. CPC H05K 3/361; H05K 1/0298; H05K 1/142; H05K 3/0076; H05K 3/0097; H05K 3/022; H05K 3/04; H05K 3/4084; H05K 2201/058

(57) ABSTRACT

Provided are a fabrication method for a long circuit board, and a long circuit board. The long circuit board is formed by overlapping and lapping m short circuit boards end to end, the short circuit board is a double-layer circuit board or a multi-layer circuit board, and includes a front circuit layer, a back circuit layer, and an intermediate insulating layer therebetween; the short circuit board is provided with multiple via holes; adjacent short circuit boards are bonded together at an overlapping position, with at least two sandwiched copper layers at the overlapping position, which include a first copper layer on one short circuit board and a second copper layer on an adjacent short circuit board; or adjacent short circuit boards are bonded together at an overlapping position, with only one sandwiched copper layer at the overlapping position, where the copper layer is located on one of the short circuit boards, and the adjacent short circuit board is bonded with the copper layer through the intermediate insulating layer; or no copper layer is sandwiched at the overlapping position, and the two intermediate insulating layers at the overlapping position are bonded together.

### TECHNICAL FIELD

The present disclosure relates to the field of circuit boards, and in particular to a fabrication method for a long circuit board and a long circuit board.

### BACKGROUND

For double-layer or multi-layer (referring to 3 layers or more) flexible circuit boards, the circuit design can be more complex and variable, thus enabling the circuit board to have a wider range of applications. To achieve interconnection and conduction between the upper and lower layers or among multiple layers of circuits, the currently common method includes: drilling holes, then forming conductive substances on the hole walls, followed by electroplating copper to form electroplated copper layer on the hole walls. The interconnection and conduction between the upper and lower layers or among multiple layers of circuits are achieved through the electroplated copper layer on the hole walls. Taking the double-layer circuit board as an example, an existing flow for fabricating the double-layer circuit board is as follows.

(1) Single-sheet fabrication method: a double-layer flexible copper-clad laminate produced in a full roll with a length of over 100 meters is cut into short copper-clad laminates with a length of less than 1 meter (including 1 meter). Afterwards, 20 or more of these short copper-clad laminates are stacked together and drilled simultaneously, followed by fabricating a conductive substance and electroplating copper on the hole wall, and then the circuit etching and other processes are carried out to fabricate a flexible circuit board with a length of 1 meter or less. Due to a short length of the flexible circuit board, in the production process of the circuit board and during attachment of an electronic component, it is impossible to implement assembly line production (full roll production) of the long board. Compared with short board production, the long board production has a higher degree of automation and high efficiency and requires less employees. With the same output, the number of workers in whole roll production is only half of that in short board production. In the full roll production, the long board is not prone to wrinkling or jamming, while in the short board production, a board corner tends to warp, causing issues such as jamming and wrinkling during assembly line processing. In addition, because the long board is required by many products, such as many products must use long boards, for example, a commercially available LED light strip with a length of 5 meters or more account for 90% of the industry share, the long flexible circuit board is required to be used, making the short board produced by the single-sheet fabrication method unable to meet the use requirements.

(2) Fabrication method for the full roll of long board: a full roll of long copper-clad laminate is drilled by a laser drilling machine. At present, single-layer drilling is used, with holes drilled section by section, resulting in particularly low efficiency. In addition, the laser drilling machine for drilling the copper-clad laminate is expensive, generally speaking, the price difference between a two-axis laser drilling machine and a two-axis ordinary pin drilling machine (mechanical drilling) is more than twice, the former is about 700,000 yuan, and the latter is about 300,000 yuan. From the point of view of working principle, the laser drilling machine can only drill a single copper-clad laminate (limited by laser penetration, which cannot drill more than one at the same time), and the ordinary pin drilling machine can drill at least 20 stacked flexible copper-clad laminates, resulting in a 20-fold difference in working efficiency and a 40-fold difference in return on investment between the ordinary pin drilling machine and the laser drilling machine. At present, in the full roll production of the long flexible double-sided circuit board, due to the necessity of using the laser drilling machine, the investment is excessively large but the input-output ratio is particularly low. This results in excessively high cost, making it difficult to popularize and promote.

To this end, the inventor has developed a fabrication method of a long board circuit board (patent application No. 202211246353.0), a short copper-clad laminate (single-layer copper) with a via hole is bonded to a bare circuit board (or a bare copper foil) to obtain a double-layer circuit board (with the short copper-clad laminate as a front copper layer and the bare circuit board or bare copper foil as a back copper layer). However, as shown in FIG. 7, it is found through practical production that as the short copper-clad laminate needs to be pressed against and bonded to the bare circuit board and an adhesive is not cured during pressing and has a certain fluidity, the adhesive is squeezed away (which is called overflowed adhesive a) under the action of the pressing force and filled on the back copper layer in the via hole, which makes the back copper layer (base copper) in the via hole partially or completely covered by the adhesive. If the base copper is completely covered by the overflowed adhesive, a defect where the upper and lower circuit layers cannot conduct at the via hole position may be caused. If the base copper is partially covered by the overflowed adhesive, the surface of the overflowed adhesive is uneven, so that a copper plating layer b bonded to an adhesive overflow position is not firm when conductive substance treatment and copper electroplating are carried out on the hole wall subsequently, leading to the formation of a void gap. When carrying out SMT (Surface Mount Technology) on the circuit board, due to the necessity of passing through a reflow oven at a temperature above 200° C., the copper bonded to the surface of the overflowed adhesive may delaminate and detach during oven passing, resulting in a low yield rate in mass production.

To this end, it is necessary to improve and optimize an existing fabrication method and structure of the long board circuit board.

### SUMMARY

The present disclosure is intended to at least solve one of the problems in the prior art. To this end, the present disclosure provides a fabrication method for a long circuit board and a long circuit board. There is no adhesive overflow in a via hole, and the copper plating layer at the via hole is firmly bonded.

The technical solution adopted by the present disclosure to solve the technical problem is as follows.

In a first aspect, an embodiment of the present disclosure provides a fabrication method for a long circuit board, including the following steps:
material preparation: preparing a long copper-clad laminate, where the long copper-clad laminate includes a front copper layer and a back copper layer on an upper surface and a lower surface of the long copper-clad laminate, and an intermediate insulating layer is disposed between the front copper layer and the back copper layer;
adhesive application: applying adhesive at intervals on the long copper-clad laminate to form multiple adhesive positions arranged at intervals in a length direction of the long copper-clad laminate;
laminate cutting: cutting the long copper-clad laminate into multiple short copper-clad laminates, where the short copper-clad laminate includes Board A with adhesive on both ends, Board A with adhesive on both ends and Board B without adhesive on both ends, or Board C with adhesive on one end;
hole making: stacking the multiple short copper-clad laminates and drilling to form via holes on the short copper-clad laminates, where each via hole penetrates through the front copper layer, the back copper layer and the intermediate insulating layer;
laminating joining: overlapping m short copper-clad laminates with pre-drilled holes end to end, where overlapping positions are bonded together with the adhesive at ends;
via hole electroplating; and
circuit fabricating.

Alternatively, in the laminate cutting process, cutting is carried out on the adhesive position to obtain Board A with adhesive on both ends; or, in the laminate cutting process, cutting is carried out outside of the adhesive position to obtain Board A with adhesive on both ends and Board B without adhesive on both ends; or, in the laminate cutting process, cutting is simultaneously carried out on the adhesive position and a long copper-clad laminate between adjacent adhesive positions to obtain Board C with adhesive on one end.

Alternatively, the method further includes a copper removal process, which includes partially removing sandwiched copper at the overlapping position to form a toothed end, and bonding overlapping positions of the ends together by the adhesive at the toothed ends; or further includes a copper removal process, which includes completely removing sandwiched copper at the overlapping position, and bonding two intermediate insulating layers together at the overlapping positions of ends by adhesive; or further includes a copper removal process, which includes partially removing sandwiched copper at the overlapping position, where only one sandwiched copper layer is at the overlapping position.

Alternatively, before adhesive application, the copper removal process is implemented on the long copper-clad laminate; or after adhesive application and before laminate cutting, the copper removal process is implemented; after laminate cutting and before hole making, the copper removal process is implemented at one end or both ends of the short copper-clad laminate; or after hole making and before laminating joining, the copper removal process is implemented at one end or both ends of the short copper-clad laminate, or after laminating joining, the copper removal process is implemented at the overlapping position.

Alternatively, the long copper-clad laminate is longer than 3 m, and the short copper-clad laminate is shorter than or equal to 3 m.

In a first aspect, an embodiment of the present disclosure provides another fabrication method for a long circuit board, including:
material preparation: preparing m short copper-clad laminates, where each short copper-clad laminate includes a front copper layer and a back copper layer on an upper surface and a lower surface thereof, and an intermediate insulating layer is disposed between the front copper layer and the back copper layer;
hole making: stacking the plurality of short copper-clad laminates and drilling to form via holes on the short copper-clad laminates, where each via hole penetrates through the front copper layer, the back copper layer and the intermediate insulating layer;
adhesive application: applying adhesive to both ends of all short copper-clad laminates to obtain Board A; or, applying adhesive to both ends of a part of the short copper-clad laminates to obtain Board A, and enabling the other short copper-clad laminates without adhesive applied to both ends to form Board B.; or, applying adhesive to one end of the short copper-clad laminate to obtain Board C;
laminating joining: overlapping m short copper-clad laminates with pre-drilled holes end to end, where overlapping positions are bonded together with the adhesive at ends;
via hole electroplating; and
circuit fabricating.

Alternatively, the fabrication method further includes a copper removal process, which includes partially removing sandwiched copper at the overlapping position to form a toothed end, and bonding overlapping positions of the ends together by the adhesive at the toothed ends; or further includes a copper removal process, which includes completely removing sandwiched copper at the overlapping position, and bonding two intermediate insulating layers together at the overlapping positions of ends by adhesive; or further includes a copper removal process, which includes partially removing sandwiched copper at the overlapping position, where only one sandwiched copper layer is at the overlapping position.

Alternatively, before hole making, the copper removal process is implemented at one end or both ends of the short copper-clad laminate; or after hole making and before glue application, the copper removal process is implemented at one end or both ends of the short copper-clad laminate; or after glue application, the copper removal process is implemented at one end or both ends of the short copper-clad laminate; or after laminating joining, the copper removal process is implemented at the overlapping position.

Alternatively, the copper removal process is as follows: simultaneously cutting away a copper layer and an intermediate insulating layer at a tooth slot position by using a die or milling cutter to obtain a fully hollowed-out tooth slot; or, removing unnecessary copper from the front copper layer or/and the back copper layer of the copper-clad laminate by using a milling cutter or laser, retaining the intermediate insulating layer at a tooth slot position to obtain a semi hollowed-out tooth slot; or, coating an anti-etching material on the copper-clad laminate to expose a position on the copper-clad laminate where the copper layer needs to be removed, and then placing the copper-clad laminate coated with the anti-etching material into an etching solution to etch and remove the front copper layer or/and the back copper layer of the copper-clad laminate which is not covered by the anti-etching material, and retaining an intermediate insulating layer at the tooth slot position to obtain a semi hollowed-out tooth slot; or, removing the copper at the end of the front copper layer or/and the back copper layer, making the end of a front side or/and a back side free of copper.

Alternatively, the adhesive application refers to adhesive printing, adhesive pasting, or adhesive dispensing.

Alternatively, the circuit board fabrication includes photoresist application, exposure, development, and circuit etching.

Alternatively, the copper-clad laminate is a double-layer board, or a multi-layer board, where an inner circuit layer is sandwiched between intermediate insulating layers, and the inner circuit layer is fabricated before drilling.

Alternatively, after circuit fabrication, the method further comprises fabricating a solder mask.

A first aspect embodiment of the present disclosure has at least one of the following beneficial effects: a copper-clad laminate with a front copper layer and a back copper layer is used as the copper-clad laminate, the long copper-clad laminate is subjected to adhesive application and cutting to obtain short copper-clad laminates, or the adhesive is directly applied to the short copper-clad laminates. Afterwards, laminating connecting is carried out, so that the adjacent short copper-clad laminates overlap end to end in the laminating joining process, the overlapping positions are bonded together by the adhesive at the ends, only the ends of adjacent short copper-clad laminates are overlapped, and the via hole can be formed away from the overlapping position, so that uncured adhesive can be prevented from flowing into the via hole to form adhesive overflow. As the copper-clad laminate is the one with the front copper layer and the back copper layer, the adhesive between the front copper layer and the back copper layer has been in a cured state. During laminating joining, the adhesive between the front copper layer and the back copper layer cannot be pressed into the via hole at the non-overlapping position to form the overflowed adhesive. That is, no adhesive overflow phenomenon is formed in the via hole in this embodiment, a long board fabrication way of bonding the short copper-clad laminate (single copper layer) onto the bare circuit board or copper foil to obtain a double-layer circuit board used before is abandoned, the defect of adhesive overflow caused by the conventional long board fabrication way is completely overcome. The long circuit board fabricated in this way features a firmly bonded copper plating layer at the via hole position, which is not easy to loosen or detach. In addition, the front copper layer and the back copper layer can form a good and reliable conduction at the via hole position. According to the embodiment of the present disclosure, multiple short copper-clad laminates are stacked and drilled, the efficiency of making the via hole is improved, and the drilled short copper-clad laminates are connected into a long board. This implements the fabrication of the full roll of long board in the subsequent process, improves the fabrication efficiency of the circuit board, and achieves a balance between cost and efficiency.

In a second aspect, an embodiment of the present disclosure provides a long circuit board, where the long circuit board is formed by overlapping and lapping m short circuit boards end to end, the short circuit board includes a front circuit layer, a back circuit layer, and an intermediate insulating layer therebetween; the short circuit board is provided with multiple via holes, and each via hole penetrates through the front circuit layer, the back circuit layer, and the intermediate insulating layer; the short circuit board is a double-layer circuit board or a multi-layer circuit board, and adjacent short circuit boards are bonded together at an overlapping position, with at least two sandwiched copper layers at the overlapping position, which include a first copper layer on one short circuit board and a second copper layer on the adjacent short circuit board; or adjacent short circuit boards are bonded together at the overlapping position, with only one sandwiched copper layer at the overlapping position, where the copper layer is located on one of the short circuit board, and the adjacent short circuit board is bonded with the copper layer at the overlapping position through the intermediate insulating layer; or no copper layer is sandwiched in the overlapping position, and the two intermediate insulating layers are the overlapping position are bonded together.

Alternatively, the two short circuit boards are in conduction with each other, either through sidewall copper, and/or through solder.

Alternatively, when the first copper layer and/or the second copper layer is disposed at the overlapping position, the first copper layer and/or the second copper layer have/has a toothed end, the toothed end comprises tooth protrusions and tooth slots, wherein the tooth protrusions form tooth protrusion circuits, part or all of the tooth protrusion circuits are connected to a circuit at a non-overlapping position, and part or all of the tooth slots disconnect adjacent circuits; or, at the overlapping position, the first copper layer and the second copper layer are not toothed.

Alternatively, at the tooth slot position, the first copper layer and/or the second copper layer are/is toothed, and the intermediate insulating layer at the tooth slot position is retained; or the first copper layer and the second copper layer are toothed, and only one intermediate insulating layer is retained at the tooth slot position; or at the tooth slot position, the intermediate insulating layer and all copper layers form tooth slots.

Alternatively, at the overlapping position, a length of the overlapping position is less than that of the tooth protrusion.

Alternatively, the long circuit board further includes a solder mask, where the solder mask covers the tooth slot; or the solder mask does not cover the tooth slot.

Alternatively, when the first copper layer and the second copper layer are disposed on the overlapping position, the first copper layer and the second copper layer are not connected to the circuit at the non-overlapping position, or at least one wire extends from the first copper layer and the second copper layer to connect the circuit at the non-overlapping position.

Alternatively, at least two circuits are connected between adjacent short circuit boards.

A second aspect embodiment of the present disclosure has at least one of the following beneficial effects: the long circuit board is formed by overlapping and lapping multiple short circuit boards end to end, where each short circuit board includes a front circuit layer, a back circuit layer and an intermediate insulating layer therebetween. Adjacent short circuit boards are bonded and fixed at an overlapping position by an adhesive layer, and a via hole can be formed away from the overlapping position, so that uncured adhesive at the overlapping position can be prevented from flowing into the via hole to form adhesive overflow. Because the adhesive in the copper-clad laminate used for fabricating the short circuit board has formed a stable cured state, the cured adhesive (which has no fluidity) around the via hole will not be squeezed into the via hole to form adhesive overflow in the subsequent drilling, laminate joining and other processes, a long board fabrication way of bonding the short copper-clad laminate (single-layer) onto the bare circuit board or copper foil to obtain a double-layer circuit board used before is abandoned, and the defect of adhesive overflow caused by the conventional long board fabrication way is completely overcome. The long circuit board fabricated in this way features a firmly bonded copper plating layer at the via hole position, which is not easy to loosen or detach. In addition, the front copper layer and the back copper layer can form a good and reliable conduction at the via hole position.

In a third aspect, an embodiment of the present disclosure provides an electronic product, including the long circuit board according to any embodiment of the second aspect, where an electronic component is soldered to the long circuit board.

Alternatively, the electronic product is a mobile phone, a vehicle, a computer, a robot, or an LED (Light Emitting Diode) light strip.

### BRIEF DESCRIPTION OF THE DRAWINGS

FIG. 1A is a diagram of a planar structure of a long coper-clad laminate according to an embodiment of the present disclosure after adhesive application;

FIG. 1B is a diagram of a planar structure of a short copper-clad laminate ((Board A)) obtained after cutting from FIG. 1A;

FIG. 1C is a diagram of another planar structure of a long coper-clad laminate according to an embodiment of the present disclosure after adhesive application;

FIG. 1D is a diagram of a planar structure of short copper-clad laminates (Board A+Board B) obtained after cutting from FIG. 1C;

FIG. 1E is a diagram of another planar structure of a long coper-clad laminate according to an embodiment of the present disclosure after adhesive application;

FIG. 1F is a diagram of a planar structure of a short copper-clad laminate (Board C) obtained after cutting from FIG. 1E;

FIG. 1G is a diagram of another planar structure of a long coper-clad laminate according to an embodiment of the present disclosure after adhesive application;

FIG. 1H is a diagram of a planar structure of a short copper-clad laminate (Board C) obtained after cutting from FIG. 1G;

FIG. 1I is a sectional diagram of FIG. 1H (the short copper-clad laminate is schematically drawn as one layer, actually including a front copper layer, a back copper layer and an intermediate insulating layer);

FIG. 2A is a diagram of a planar structure of FIG. 1D after hole making;

FIG. 2B is a diagram of a planar structure of a long board formed by overlapping short copper-clad laminates in FIG. 2A end to end;

FIG. 2C is a diagram of a planar structure of FIG. 2B after etching;

FIG. 2D is a diagram of a planar structure of FIG. 2C. after a solder mask is fabricated;

FIG. 2E is a diagram of a planar structure of a short coper-clad laminate according to an embodiment of the present disclosure after hole making (without adhesive application);

FIG. 3A is a diagram of a three-dimensional structure of two adjacent short copper-clad laminates at position A in FIG. 2B when not overlapping (there is no toothed end and a via hole is not drawn);

FIG. 3B is a diagram of a sectional structure of a short copper-clad laminate in FIG. 3A;

FIG. 3C is a diagram of a three-dimensional structure of two short copper-clad laminates in FIG. 3A when overlapping end to end;

FIG. 3D is a diagram of a positive projection of two short copper-clad laminates in FIG. 3C when overlapping end to end;

FIG. 3E is a diagram of a sectional structure of FIG. 3D at an overlapping position;

FIG. 3F is a diagram of a three-dimensional structure of FIG. 3C after electroplating (the surface is attached with electroplated copper);

FIG. 3G is a diagram of a sectional structure of FIG. 3F at an overlapping position;

FIG. 3H is a diagram of a three-dimensional structure of FIG. 3F after etching;

FIG. 3I is a diagram of a sectional structure of FIG. 3H at an overlapping position;

FIG. 4A is a diagram of a three-dimensional structure of two adjacent short copper-clad laminates at position A in FIG. 2B when not overlapping (one of the short copper-clad laminates has a toothed end, and a via hole is not drawn);

FIG. 4B is a diagram of a three-dimensional structure of two short copper-clad laminates in FIG. 4A when overlapping end to end;

FIG. 4C is a diagram of a sectional structure of FIG. 4B at an overlapping position;

FIG. 4D is a diagram of a three-dimensional structure of FIG. 4B after electroplating (the surface is attached with electroplated copper);

FIG. 4E is a diagram of a sectional structure of FIG. 4D at an overlapping position;

FIG. 4F is a diagram of a three-dimensional structure of FIG. 4D after etching;

FIG. 4G is a diagram of a sectional structure of FIG. 4F at an overlapping position;

FIG. 5A is a diagram of a three-dimensional structure of two adjacent short copper-clad laminates at position A in FIG. 2B when not overlapping (both short copper-clad laminates have a toothed end, and a via hole is not drawn);

FIG. 5B is a diagram of a three-dimensional structure of two short copper-clad laminates in FIG. 5A when overlapping end to end;

FIG. 5C is a diagram of a sectional structure of FIG. 5B at an overlapping position;

FIG. 5D is a diagram of a three-dimensional structure of FIG. 5B after electroplating (the surface is attached with electroplated copper);

FIG. 5E is a diagram of a sectional structure of FIG. 5D at an overlapping position;

FIG. 5F is a diagram of a three-dimensional structure of FIG. 5D after etching;

FIG. 5G is a diagram of a sectional structure of FIG. 5F at an overlapping position;

FIG. 5H is a diagram of a sectional structure of FIG. 5F at a non-overlapping position;

FIG. 6A is a cross-sectional diagram of a short copper-clad laminate at a via hole position;

FIG. 6B is a cross-sectional diagram of FIG. 6A after electroplating;

FIG. 6C is a structural diagram of multiple short copper-clad laminates after laminate joining;

FIG. 6D is another structural diagram multiple short copper-clad laminates after laminate joining;

FIG. 7 is a diagram of a sectional structure when there is overflowed adhesive on a double-layer circuit board in the prior art (a copper plating layer cannot be firmly bonded to base copper at an adhesive overflow position).

Reference numerals are as follows: 1—long copper-clad laminate; 11—front copper layer; 12—back copper layer; 13—intermediate insulating layer; 131—insulating film; 132—adhesive layer; 2—adhesive location; 3—short copper-clad laminate; 4—via hole; 5—toothed end; 51—tooth protrusion; 52—tooth slot; 6—short circuit board; 61—front circuit layer; 62—back circuit layer; 63—first copper layer; 64—second copper layer; 65—sidewall copper; 7—solder mask; a—overflowed adhesive; 6—copper plating layer.

### DETAILED DESCRIPTION OF THE EMBODIMENTS

To make the objective, technical solutions and advantages of the present disclosure more clearly, the embodiments of the present disclosure are described in detail below with reference to accompanying drawings. It should be noted that the embodiments below and features in the embodiments can be mutually combined in the case of no conflict.

Numerous different implementations or examples are provided below to implement methods and structures in the present disclosure.

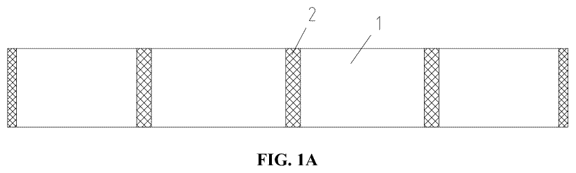

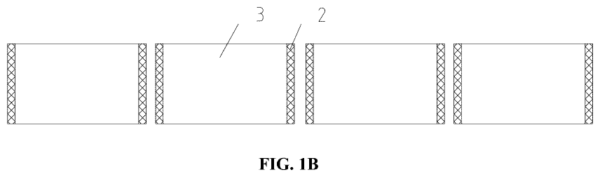

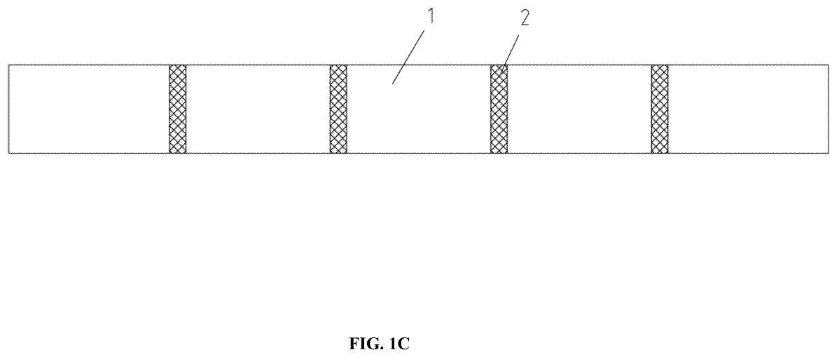

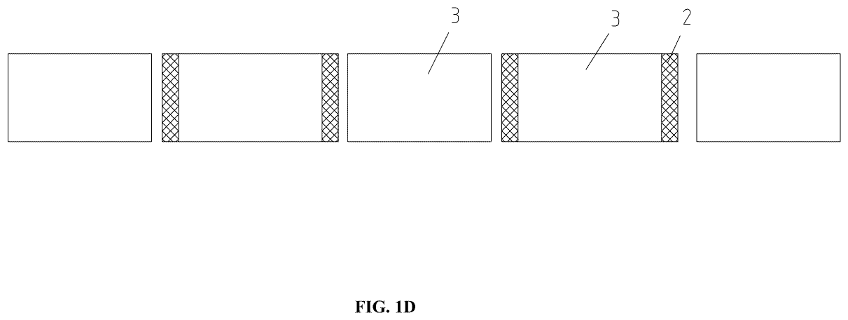

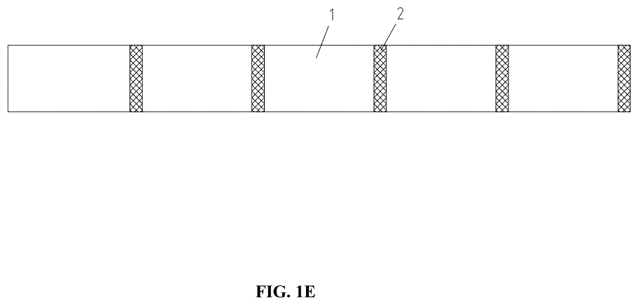

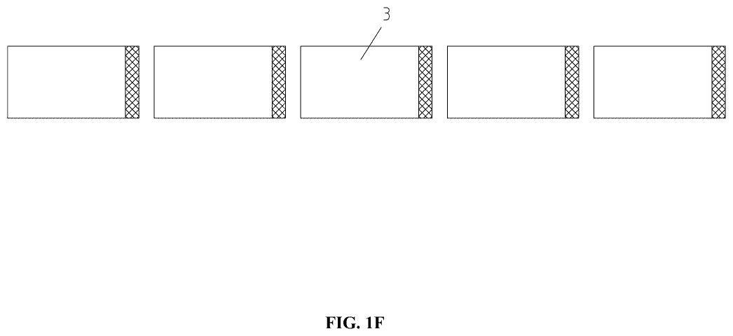

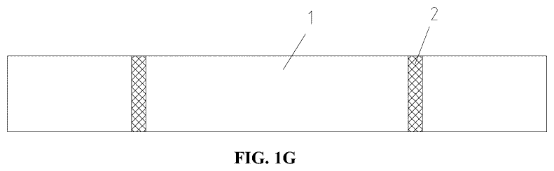

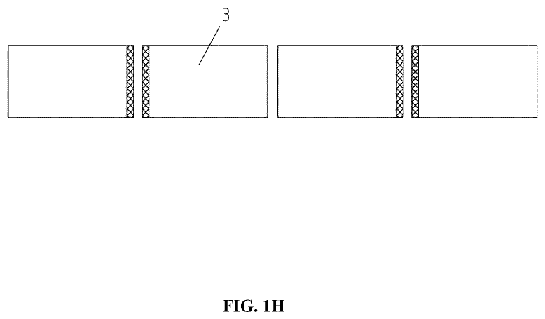

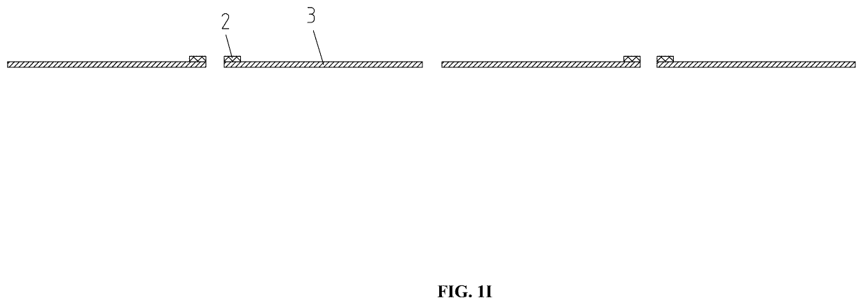

With reference to FIG. 1A to FIG. 5H, a first aspect embodiment of the present disclosure provides a fabrication method for a long circuit board.

### Embodiment 1

Material preparation: a long copper-clad laminate 1 is prepared, which is a copper-clad laminate with a length longer than 3 meters. In this embodiment, the length of the long copper-clad laminate is 30 meters, and the long copper-clad laminate includes a front copper layer 11 and a back copper layer 12 located on upper and lower surface thereof, and there is an intermediate insulating layer 13 between the front copper layer 11 and the back copper layer 12. The long copper-clad laminate 1 may be a double-layer copper-clad laminate, that is, there are only the front copper layer and the back copper layer, or the long copper-clad laminate may be a multi-layer copper-clad laminate. In the industry, multi-layer refers to three or more layers. For example, three layers are respectively a front copper layer, a back copper layer and a copper layer sandwiched between the front copper layer and the back copper layer. The sandwiched copper layer has been fabricated into a circuit to form an inner circuit layer. The long copper-clad laminate is a mature technology in the art and will not be described in detail here.

Adhesive application: the adhesive is applied to the long copper-clad laminate 1 at intervals to form multiple adhesive positions 2 arranged at intervals in a length direction of the long copper-clad laminate 1. The method of adhesive application may be adhesive printing, such as pad printing; or adhesive pasting, that is, an adhesive tape is pasted to the long copper-clad laminate, or adhesive dispensing, that is, the adhesive is dispensed by an adhesive dispenser. With reference to FIG. 1A, FIG. 1C, FIG. 1E and FIG. 1G, each is a diagram of a planar structure of a long copper-clad laminate after adhesive application at intervals.

Laminate cutting: the long copper-clad laminate is cut into multiple short copper-clad laminates 3 by a cutting machine, where the short copper-clad laminate refers to a copper-clad laminate with a length shorter than or equal to 3 m. In this embodiment, the number of short copper-clad laminates obtained by cutting is 20. Different short copper-clad laminates are obtained based on different cutting positions, the short copper-clad laminates 3 obtained by cutting may be Board A with adhesive on both ends (as show in FIG. 1B), may consist of a part of Board A with adhesive at both ends and a part of Board B without adhesive at both ends (as shown in FIG. 1.4), or may be Board C with adhesive at one end (as shown in FIG. 1F and FIG. 1H). Specifically, with reference to FIG. 1A and FIG. 1B, in the laminate cutting process, cutting is carried out on the adhesive positions of the long copper-clad laminate with adhesive shown in FIG. 1A to obtain Board A with adhesive at both ends shown in FIG. 1B. Alternatively, with reference to FIG. 1C and FIG. 1D, in the laminate cutting process, the cutting is carried out outside the adhesive positions to obtain two types of short copper-clad laminates, one is Board A with adhesive on both ends, and the other is Board B without adhesive on both ends. Alternatively, as shown in FIG. 1G and FIG. 1.8, in the laminate cutting process, the cutting is carried out on the adhesive positions and a long copper-clad laminate between adjacent adhesive positions to obtain short copper-clad laminates, that is, Board C with adhesive at one end. As shown in FIG. 1E and FIG. 1F, cutting is carried out at one side of the adhesive position to obtain the short copper-clad laminate, which is Board C with adhesive at one end.

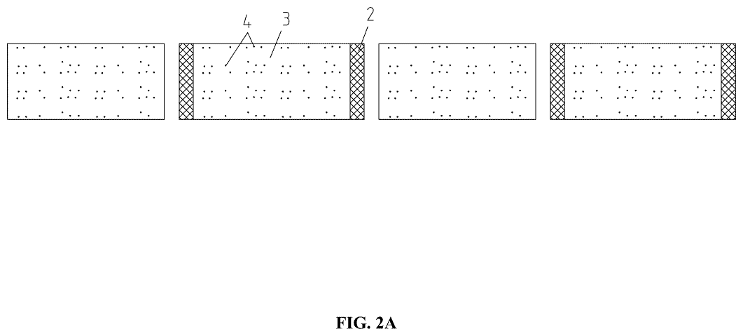

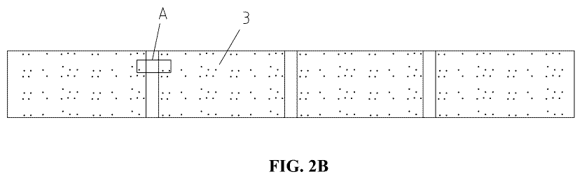

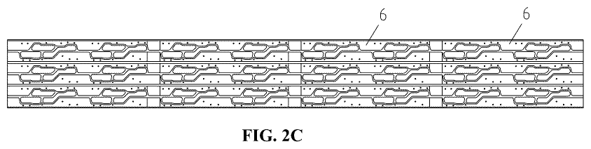

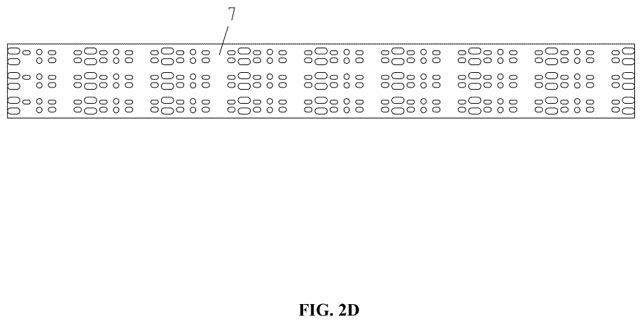

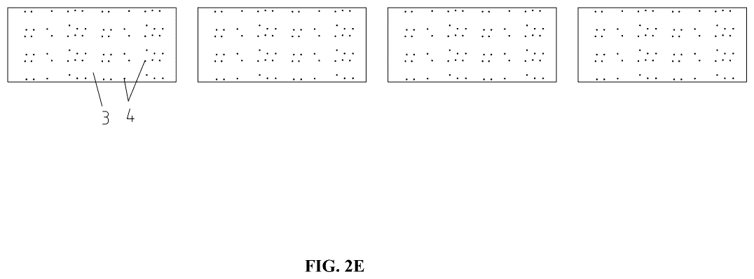

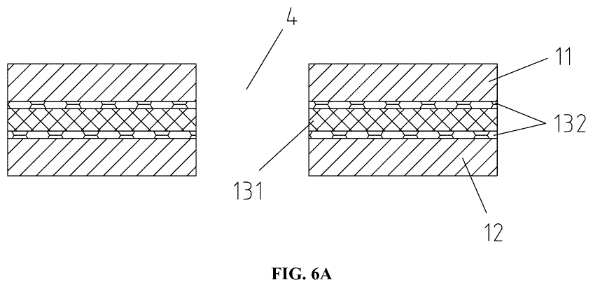

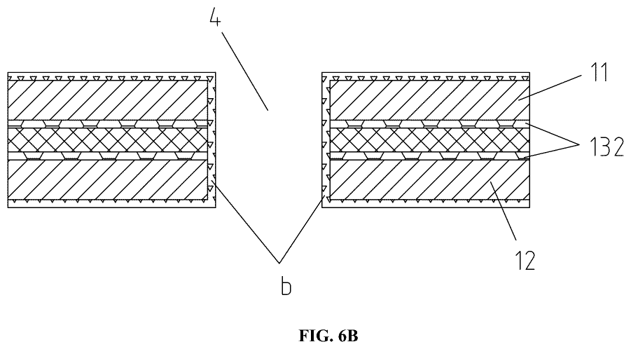

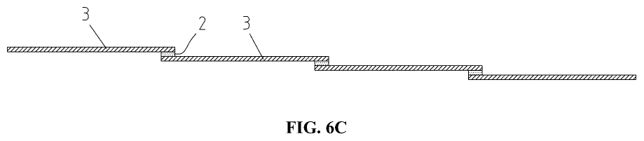

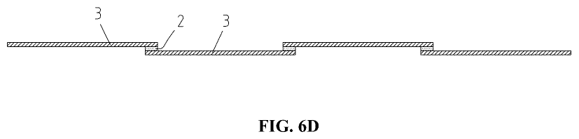

Hole making: after multiple short copper-clad laminates are stacked, a pin drilling machine is used for drilling to form a via hole 4 in the short copper-clad laminated. Compared with the conventional single drilling of the long copper-clad laminate, the short copper-clad laminates are stacked and then drilled in this embodiment, holes can be formed in multiple short copper-clad laminates at one time, so that the hole making efficiency is high, and the obtained via hole penetrates through the front copper layer, the back copper layer and the intermediate insulating layer. When the multiple short copper-clad laminates are stacked, to prevent the adhesive on the short copper-clad laminate from bonding other short copper-clad laminates stacked thereon, a release paper can be disposed on the adhesive. For example, for adhesive application of pasting an adhesive tape, the applied adhesive tape comes with pre-attached release paper. For adhesive application with printing or dispensing, the release paper can be made on the adhesive after adhesive application. For the via hole, with reference to FIG. 2B and FIG. 6A to FIG. 6B, the via hole formed in this embodiment penetrates through the front copper layer 1, the back copper layer 12 and the intermediate insulating layer 13, where the intermediate insulating layer 13 includes an insulating film 131 and adhesive layers 132 on upper and lower surfaces of the insulating film 131, and the adhesive layer 132 is configured to bond the front copper layer 11 and the back copper layer 12.

Laminate joining: the m short copper-clad laminates 3 with holes overlap end to end, with overlapping positions bonded together by the adhesive at the ends. In the laminate cutting process, the obtained short copper-clad laminates have various conditions. When Board A with adhesive at both ends as shown in FIG. 1B is obtained, the Board A is overlapped end to end and then pressed by a laminating machine to bond two adjacent short copper-clad laminates together by the adhesive at the overlapping position. When Board A and Board B shown in FIG. 1D are obtained by cutting, one of the two adjacent short copper-clad laminates is Board A and the other is Board B. When Board C shown in FIG. 1F or FIG. 1H is obtained by cutting, the two adjacent short copper-clad laminates are both Board C, where one end with adhesive overlap with one end without adhesive. According to the different laminate joining modes, multiple adjacent short copper-clad laminates 3 are joined, with reference to FIG. 6C and FIG. 6D.

Via hole electroplating: a layer of conductive substance is fabricated on a hole wall of the via hole and a sidewall of the overlapping position, the conductive substance can be fabricated on a black hole line a polymer conductive adhesive line or an electroless copper plating line, and the conductive substance is graphite, polymer conductive adhesive, or copper (all of which are the prior art). Then, electroplating is carried out to form a copper plating layer on the hole wall of the via hole and the sidewall of the overlapping position, where the copper plating layer in the via hole is configured to connect the front copper layer with the back copper layer, and the copper plating layer (sidewall copper) on the sidewall is configured to connect the short copper-clad laminates on both sides of the overlapping position. Because the adhesive on the intermediate insulating layer that bonds the front copper layer and the back copper layer has cured during the fabrication of the via hole, the hole wall of the via hole is free from adhesive overflow, and the hole wall of the via hole is straight, so that the copper plating layer is firmly bonded in the via hole and no void can be formed. A thickness of the conductive substance is particularly thin, only about 1 μm. After electroplating, the copper plating layer and the conductive substance are integrated. The action of the conductive substance is that the hole wall and the sidewall are electrically connected to connect the hole wall and each copper layer at the sidewall. However, this layer of conductive substance is too thin and has insufficient conductivity, it is necessary to perform additional copper plating to achieve sufficient conductivity. During electroplating, the hole wall and the side wall need to be conductive to form a current path, so that a copper plating layer can be formed on the hole wall and the side wall.

Circuit fabrication: a circuit fabrication method is a well-known technology in the art, and specifically, the circuit can be fabricated by adopting an etching method, including hole photoresist application, exposure, development and circuit etching.

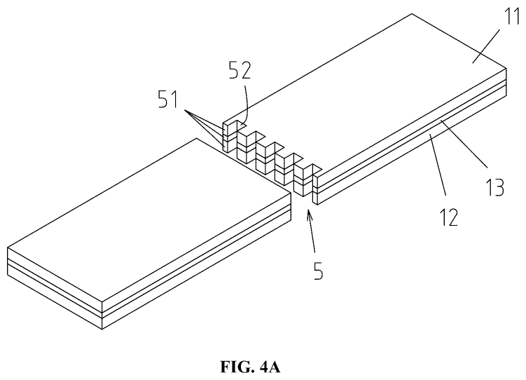

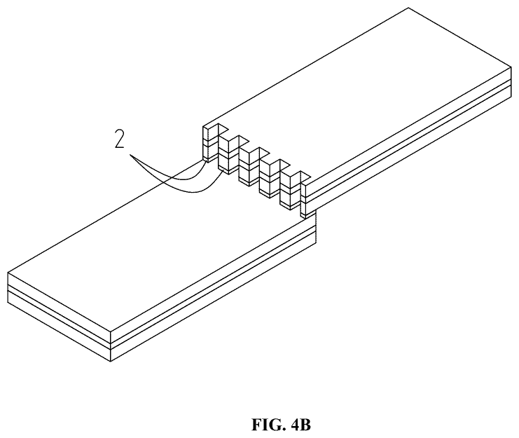

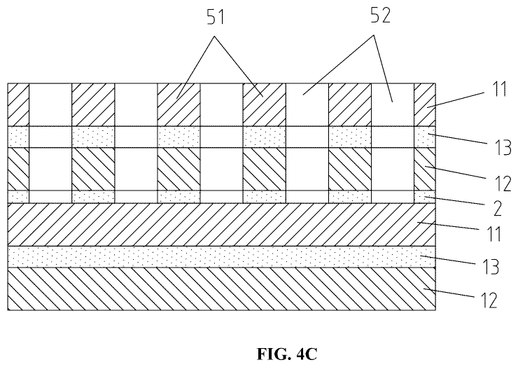

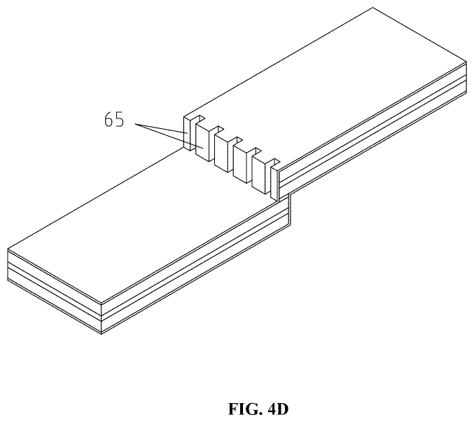

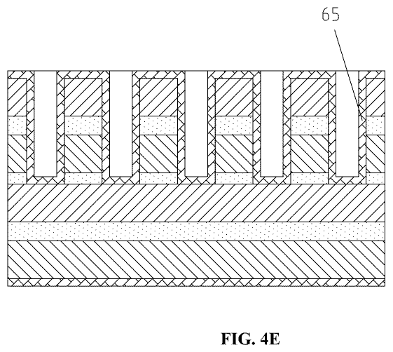

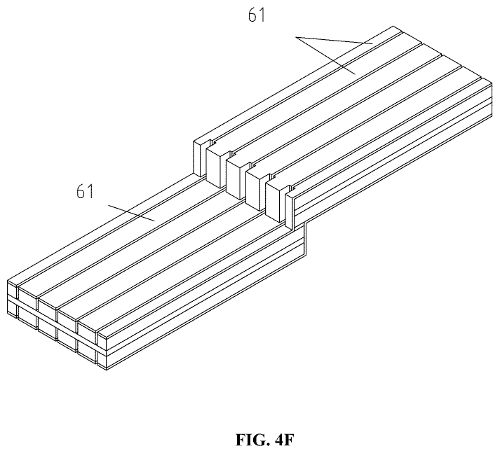

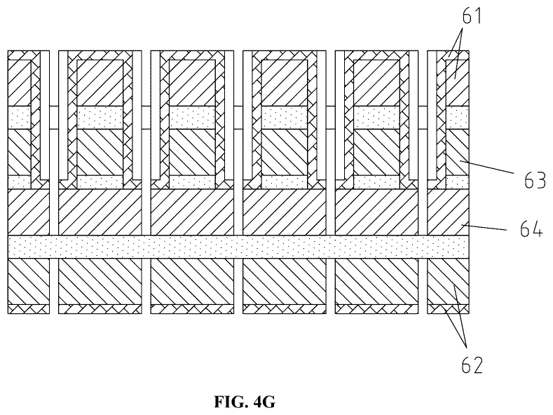

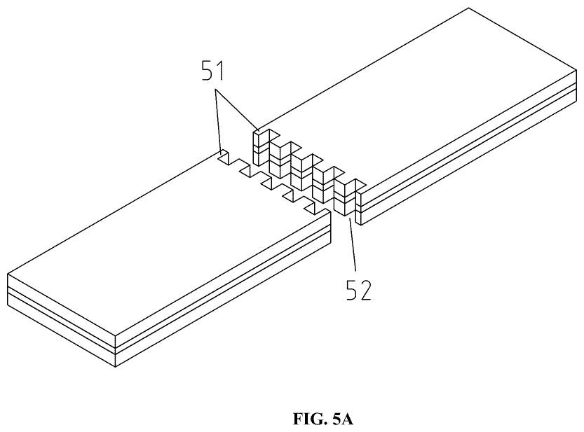

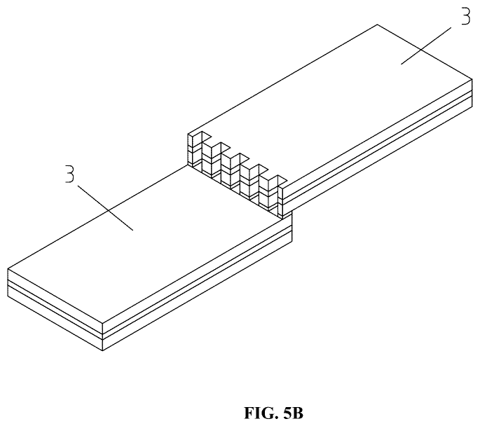

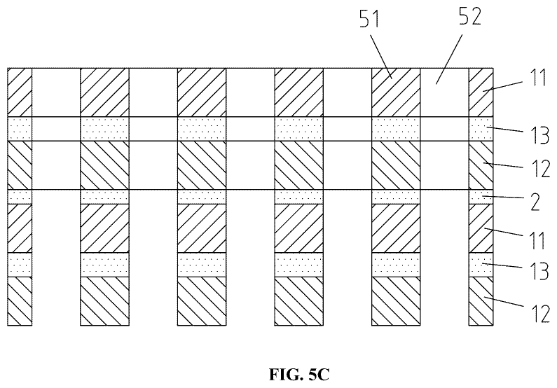

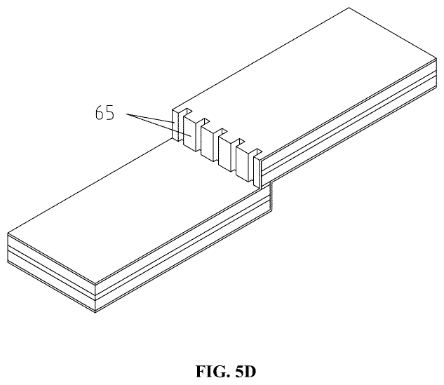

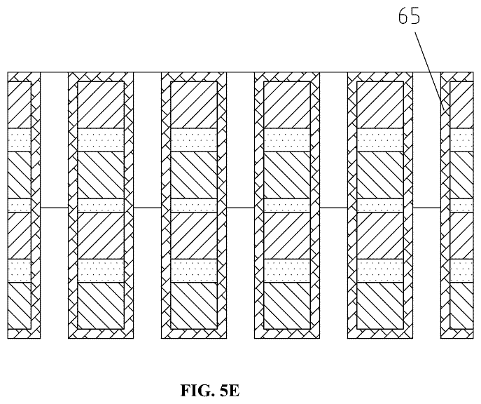

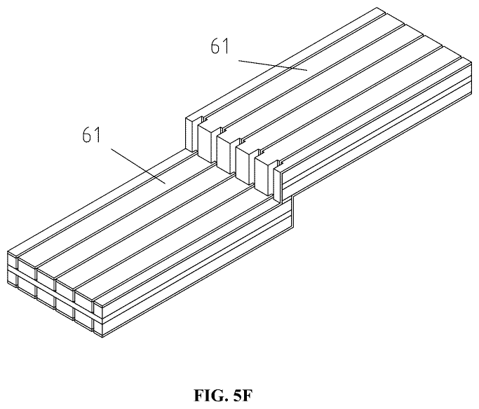

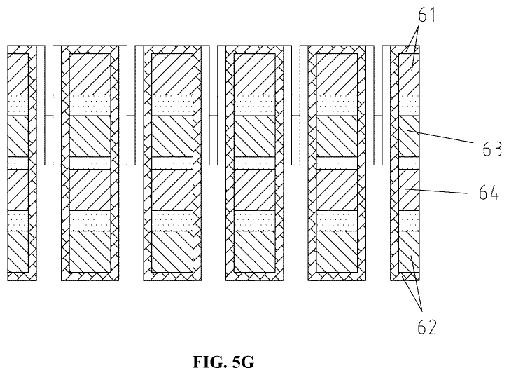

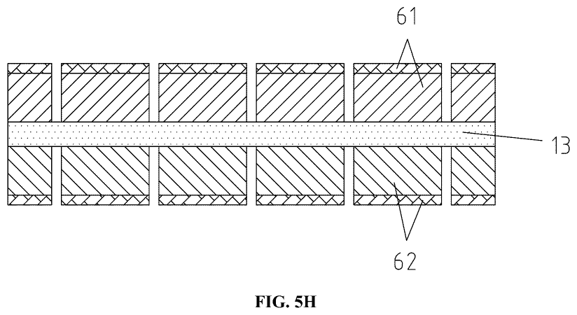

In some embodiments, the method further includes a copper removal process, including partially removing sandwiched copper at the overlapping position to form a toothed end 5, where the end-to-end overlapping positions are bonded together by the adhesive at the toothed end 5, as shown in FIG. 4A-FIG. 5G. The toothed end can be arranged on one of the adjacent short copper-clad laminates, as shown in FIG. 4A, or both adjacent short copper-clad laminates may both be provided with toothed ends, as shown in FIG. 5A. In some other embodiments of the present disclosure, the method further includes a copper removal process, including completely removing sandwiched copper at the overlapping position, where two intermediate insulating layers are bonded together by adhesive at the end-to-end overlapping position, that is, there is no sandwiched copper at the overlapping position (the sandwiched copper does not include a sandwiched inner circuit layer of the multi-layer board itself). Specifically, each of the upper and lower surfaces of the adhesive that bonds the overlapping positions is bonded with the intermediate insulating layer, not the copper layer. In some other embodiments, the method further includes a copper removal process, including partially removing sandwiched copper at the overlapping position, where there is only one sandwiched copper layer at the overlapping position, that is, one lay of copper of one of two adjacent short copper-clad laminates at an overlapping end is removed to expose the intermediate insulating layer, and the copper of the other short copper-clad laminate at the overlapping end is not removed.

The copper removal process can be implemented in different stages. Specifically, in some embodiments, before adhesive application, the copper removal process is implemented on the long copper-clad laminate, and after the long copper-clad laminate is prepared, the copper removal can be implemented at a position where the adhesive to be applied by a mold or a milling cutter, and the adhesive can be applied after copper removal. In some embodiments of the present disclosure, after adhesive application and before laminate cutting, the copper removal process is implemented. That is, after adhesive application, the unnecessary copper at an adhesive application position and an adhesive at a position corresponding to the unnecessary copper are removed together by a die or a milling cutter. It may be understood that this method is suitable for forming the toothed end. In some embodiments of the present disclosure, after laminate cutting and hole making, the copper removal process is implemented at one or both ends of the short copper-clad laminate, and the toothed end may also be formed. In some other embodiments, after hole making and before laminating joining, the copper removal process can also be implemented at one or both ends of the short copper-clad laminate. In some other embodiments, after laminate joining, the copper removal process can be implemented at the overlapping position. This method is suitable for a case of forming the toothed end, and the unnecessary copper, the adhesive at a position and the intermediate insulating layer are removed together.

The foregoing embodiments are implemented by applying adhesive to the long copper-clad laminate, followed by laminate cutting. However, it is not the unique way. To this end, a first aspect embodiment of the present disclosure further provides another fabrication method for a long circuit board.

### Embodiment 2

Material preparation: m short copper-clad laminates 3 are prepared, where each short copper-clad laminate includes a front copper layer 11 and a back copper layer 12 on an upper surface and a lower surface thereof, and an intermediate insulating layer 13 is disposed between the front copper layer 11 and the back copper layer 12, where a length of the short copper-clad laminate is shorter than or equal to 3 meters.

Hole making: the multiple short copper-clad laminates 3 are stacked and drilled to form via holes 4 in the short copper-clad laminates, where the via hole can be formed in the multiple short copper-clad laminates by one-time drilling, the hole making efficiency is improved. With reference to FIG. 2E, the via hole penetrates through the front copper layer, the back copper layer and the intermediate insulating layer.

Adhesive application: adhesive is applied to both ends of all short copper-clad laminates to obtain Board A; or, the adhesive is applied to both ends of a part of the short copper-clad laminates to obtain Board A, and no adhesive is applied to both ends of the other part of short copper-clad laminates to form Board B; or, the adhesive is applied to one end of the short copper-clad laminate to obtain Board C. It may be understood that in this embodiment, the adhesive application may be applied after hole making or before hole making. It may be understood that the adhesive application is not limited to the foregoing three ways.

Laminating joining: m short copper-clad laminates 3 with holes are overlapped end to end, where overlapping positions are bonded together with the adhesive at the ends.

Via hole electroplating is specifically the same as in Embodiment 1.

Circuit fabrication: the circuit fabrication is the same as that in Embodiment and thus is not described in detail here.

In Embodiment 2, the copper removal process may also be carried out to partially remove sandwiched copper at the overlapping position to form a toothed end, and end-to-end overlapping positions are bonded together by the adhesive at the toothed end. Alternatively, the copper removal process is carried out to completely remove sandwiched copper at the overlapping position, and two intermediate insulating layers are bonded together at the end-to-end overlapping position by adhesive Alternatively, the copper removal process is carried out to partially remove sandwiched copper at the overlapping position, where there is only one sandwiched copper layer at the overlapping position.

In Embodiment 2, the copper removal process may be implemented at different stages. Specifically, before hole making, the copper removal process is implemented at one end or both ends of the short copper-clad laminate. Alternatively, after hole making and before adhesive application, the copper removal process is implemented at one end or both ends of the short copper-clad laminate. Alternatively, after adhesive application, the copper removal process is implemented at one end or both ends of the short copper-clad laminate. Alternatively, after laminate joining, the copper removal process is implemented at the overlapping position.

In Embodiment 1 and Embodiment 2, there may be different choices for the copper removal ways in the copper removal process, such as, whether to remove the intermediate insulating layer between the front copper layer and the back copper layer at the same time during copper removal, and whether to remove all copper during copper removal. Specifically, in some embodiments, the copper removal process is as follows: a copper layer as well as the intermediate insulating layer at a tooth slot position are cut away simultaneously by using a mold or milling cutter to obtain a fully hollowed-out tooth slot, with reference to FIG. 4A and FIG. 5A. for specific details. In some other embodiments, unnecessary copper is removed from the front copper layer or/and the back copper layer of the copper-clad laminate by using a milling cutter or a laser, and the intermediate insulating layer at the tooth slot position is retained, thereby obtaining a semi hollowed-out tooth slot. In some other embodiments, the copper can be removed by using an etching method. Specifically, an anti-etching material (well-known material) is coated on the copper-clad laminate to expose a position on the copper-clad laminate where the copper layer needs to be removed, and then the copper-clad laminate coated with the anti-etching material is placed into an etching solution to etch and remove the front copper layer or/and the back copper layer of the copper-clad laminate which is not covered by the anti-etching material, and an intermediate insulating layer at the tooth slot position is retained, thereby obtaining a semi hollowed-out tooth slot. Alternatively, the copper at the end of the front copper layer or/and the back copper layer are all removed, making the end of a front side or/and a back side free of copper. In this case, the sandwiched copper at the overlapping position is completely removed, and two intermediate insulating layers are bonded together by the adhesive at the end-to-end overlapping position.

In Embodiment 1 and Embodiment 2, after circuit fabrication, the method further includes fabricating a solder mask, and the obtained long circuit board is a complete circuit board. The fabrication of the solder mask includes fabricating a front solder mask and fabricating a back solder mask. The solder mask may be a solder mask thin film, such as PET (Polyethylene Terephthalate) film, or solder mask ink.

In Embodiment 1 and Embodiment 2, a copper-clad laminate (The prior art uses a short copper-clad laminate with a single copper layer, which is bonded to a bare circuit board or copper foil) with a front copper layer and a back copper layer is used as the copper-clad laminate, the long copper-clad laminate is subjected to adhesive application and cutting to obtain short copper-clad laminates, or the adhesive is directly applied to the short copper-clad laminates. Afterwards, laminating connecting is carried out, so that the adjacent short copper-clad laminates overlap end to end in the laminating joining process, the overlapping positions are bonded together by the adhesive at the ends, only the ends of adjacent short copper-clad laminates are overlapped, and the via hole can be formed away from the overlapping position (in the prior art, the short copper-clad laminate with a single copper layer is entirely attached and overlapped to the bare circuit board or copper foil, which makes the via hole in the short copper-clad laminate with a single copper layer cannot avoid the overlapping position, and during bonding and overlapping, the adhesive between the short copper-clad laminate and the bare circuit board (or metal foil) is in an uncured state, and the uncured state may enter the via hole to form adhesive overflow). In this embodiment, as the copper-clad laminate is the one with the front copper layer and the back copper layer, the adhesive between the front copper layer and the back copper layer has been in a cured state. During laminating joining, the adhesive between the front copper layer and the back copper layer cannot be squeezed out by the pressing force during laminating joining to overflow to the hole wall of the via hole. That is, no adhesive overflow phenomenon can be formed in the via hole in this embodiment. A long board fabrication way of bonding the short copper-clad laminate (single copper layer) onto the bare circuit board or copper foil to obtain a double-layer circuit board used before is abandoned, the defect of adhesive overflow caused by the conventional long board fabrication way is completely overcome. The long circuit board fabricated in this way features a firmly bonded copper plating layer at the via hole position, which is not easy to loosen or detach. In addition, the front copper layer and the back copper layer can form a good and reliable conduction at the via hole position. According to the embodiment of the present disclosure, multiple short copper-clad laminates are stacked and drilled, the efficiency of making the via hole is improved, and the drilled short copper-clad laminates are connected into a long board. This implements the fabrication of the full roll of long board in the subsequent process, improves the fabrication efficiency of the circuit board, and achieves a balance between cost and efficiency.

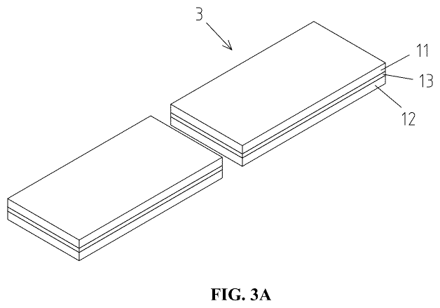

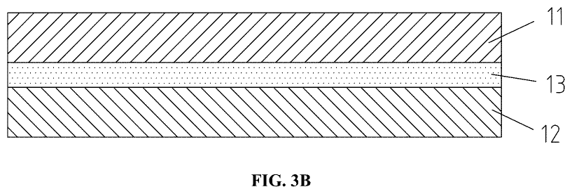

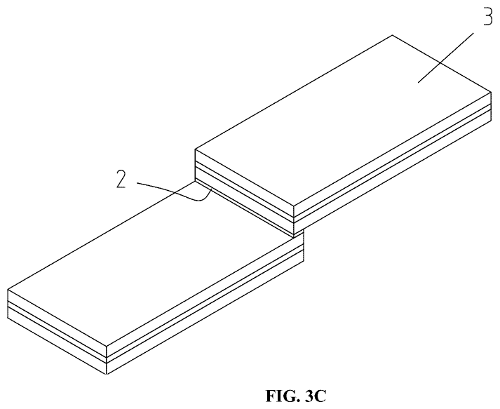

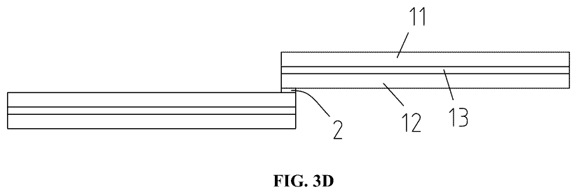

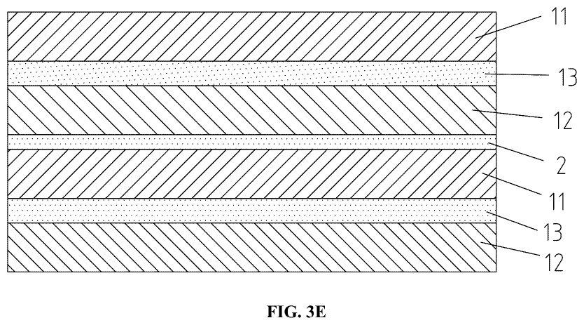

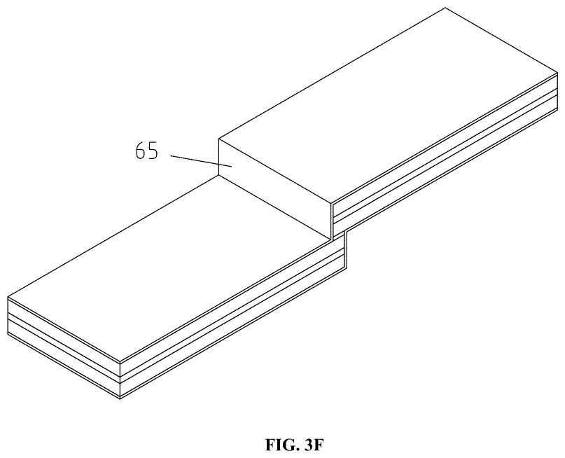

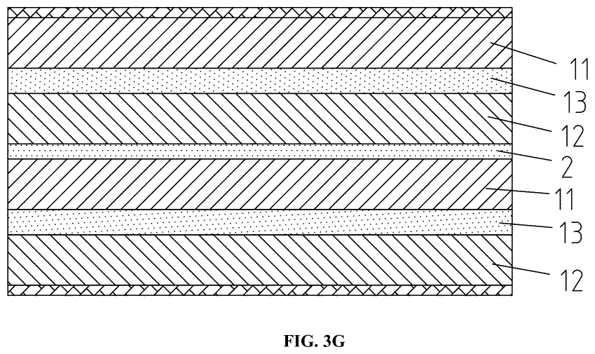

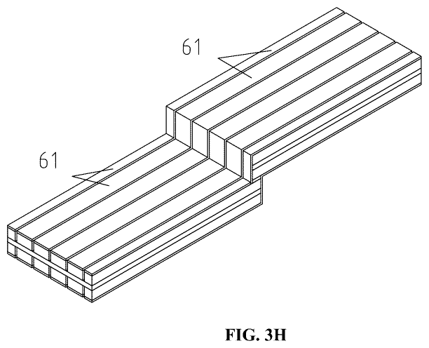

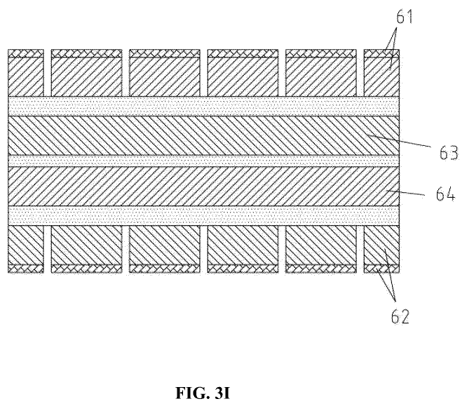

According to methods in Embodiment 1 and Embodiment 2, an embodiment of the second aspect of the present disclosure can be obtained. With reference to FIG. 3H, FIG. 3I, FIG. 4F, FIG. 4G, FIG. 5F and FIG. 5G, a long circuit board is formed by overlapping and lapping m segments of short circuit boards 6 end to end, the short circuit board 6 includes a front circuit layer 61, a back circuit layer 62, and an intermediate insulating layer 13 between the front circuit layer 61 and the back circuit layer 62. The short circuit board 6 is provided with multiple via holes 4, and the via hole 4 penetrates through the front circuit layer 61, the back circuit layer 62 and the intermediate insulating layer 13. The short circuit board is a double-layer circuit board or a multi-layer circuit board, and adjacent short circuit boards 6 are bonded together at an overlapping position, with at least two sandwiched copper layers at the overlapping position, which include a first copper layer 63 on one short circuit board and a second copper layer 64 on the adjacent short circuit board, that is, in the two adjacent short circuit boards, the one positioned on the top is called a upper circuit board and the other positioned below is called a lower circuit board. At the overlapping position, the back circuit layer of the upper circuit board is not removed or not completely removed, and the front circuit layer of the lower circuit board is not removed or not completely removed. Alternatively, adjacent short circuit boards 6 are boned together at an overlapping position, with only one sandwiched copper layer at the overlapping position, where the copper layer is located on one of the short circuit boards, and the adjacent short circuit boards are bonded with the copper layer through an intermediate insulating layer at the overlapping position. That is, the back circuit layer of the upper circuit layer is not removed or not completely removed, and the front circuit layer of the lower circuit board is completely removed to expose the intermediate insulating layer. Alternatively, the front circuit layer of the lower circuit board may also be retained, and the back circuit layer of the upper circuit board is removed to expose the intermediate insulating layer. Alternatively, there is no sandwiched copper layer at the overlapping position, the two intermediate insulating layers at the overlapping position are bonded together. That is, at the overlapping position, the metals on the back circuit layer of the upper circuit layer and the front circuit layer of the lower circuit board are completely removed to expose respective intermediate insulating layers, respectively, and the two intermediate insulating layers are bonded together. It may be understood that in this embodiment, the bonding is implemented by means of adhesive.

In some embodiments of the present disclosure, with reference to FIG. 3H, FIG. 3I, FIG. 4F, FIG. 4G, FIG. 5F and FIG. 5G, the two adjacent short circuit boards are in conduction with each other. Specifically, the conduction may be achieved through sidewall copper 65, the sidewall copper 65 is a copper plating layer formed in an electroplating process. In some other embodiments of the present disclosure, the conduction between two adjacent short circuit boards can be achieved by soldering connection, and the soldering connection can be carried out while the electronic product is soldered. Therefore, the long circuit board can be directly used as a long board after the electronic component is soldered.

In some embodiments of the present disclosure, when there is the first copper layer 63 and/or the second copper layer 64 at the overlapping position, the first copper layer 63 and/or the second copper layer 64 have/has a toothed end 5, the toothed end 5 includes tooth protrusions 51 and tooth slots 52, and the tooth protrusions 51 form a tooth protrusion circuit. According to the design requirements of the circuit, the tooth protrusion circuit used as the circuit can be completely connected to the circuit at a non-overlapping position or partially connected to the circuit at the non-overlapping position. The tooth slot 52 can completely or partially disconnect the adjacent circuits (width directions of the circuit boards are adjacent to each other). In some other embodiments of the present disclosure, the first copper layer 63 and the second copper layer 64 do not have teeth at the overlapping position. If a short circuit occurs due to the existence of the first copper layer and/or the second copper layer, the long circuit board can be cut at the overlapping position to form short circuit boards. Specifically, in some embodiments, when producing the long circuit board, the LED light strip is fabricated using a full-roll process. After the LED light strip is fabricated, the LED light strip at the overlapping position for use, or cut into circuit board segments for use before an electronic component is soldered.

There are many situations about the tooth slot position. Specifically, at the tooth slot position, the first copper layer and/or the second copper layer are/is toothed, and an intermediate insulating layer at the tooth slot position is retained. Alternatively, the first copper layer and the second copper layer are toothed, and only one intermediate insulating layer is retained at the tooth slot position, that is, the intermediate insulating layer at the tooth slot position on the short board associated with the first copper layer (or the second copper layer) is retained, while that on the short board associated with the second copper layer (or the first copper layer) is removed. Alternatively, at the tooth slot position, the intermediate insulating layer and all copper layers form a tooth slot. That is, the intermediate insulating layer may be retained at the tooth slot position, or there may be no intermediate insulating layer at the tooth slot position. This is brought about by the way of forming the toothed end, and the forming way of the toothed end has been described in detail above.

With the tooth-shaped end, when the adjacent circuits are disconnected by the tooth slot, the sandwiched copper at the overlapping position can be divided into multiple circuits, so that the circuit board can be prevented from short-circuit at the overlapping position, and the circuit board can be directly used as a long board after an electronic component is soldered.

In some embodiments of the present disclosure, at the overlapping position, a length of the overlapping position is shorter than that the tooth protrusion, so that the tooth slot can separate the copper layers at the overlapping position to avoid short circuit.

In some embodiments, the long circuit board further includes a solder mask 7, where the solder mask covers the tooth slot 52. Alternatively, the solder mask does not cover the tooth slot 52.

When there are the first copper layer and the second copper layer at the overlapping position, the first copper layer and the second copper layer are not connected to the circuit at the non-overlapping position. After the electronic component is soldered to the long circuit board, cutting is carried out at the overlapping position to obtain short LED light strips. Alternatively, at least one wire extends to connect the circuit at the non-overlapping position. Therefore, the LED light strip fabricated from the long circuit board can be used as a long light strip.

In some embodiments of the present disclosure, there are at least two circuits connected between adjacent short circuit boards 6. Typically, there are two main wires (positive and negative) connected, so that the long circuit board can be used as a long board. The specific connection can be achieved through the foregoing toothed ends and sidewall copper.

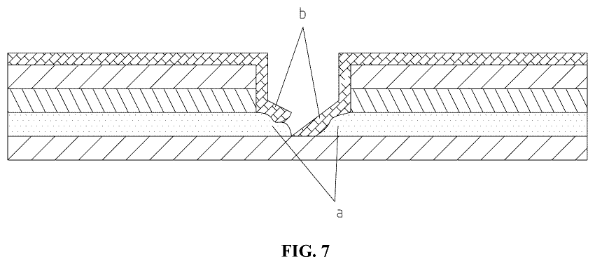

As can be learned from above analysis that the long circuit board according to the embodiment of the present disclosure is formed by overlapping and lapping multiple short circuit boards end to end, where the short circuit board includes a front circuit layer, a back circuit layer and an intermediate insulating layer therebetween. Adjacent short circuit boards are bonded and fixed at an overlapping position by an adhesive layer, the via hole can be formed away from the overlapping position, so that uncured adhesive can be prevented from flowing into the via hole to form adhesive overflow. As the adhesive in the copper-clad laminate for fabricating the short circuit board has formed a stable cured state, so that during subsequent drilling and laminating joining processes, the adhesive in the cured state (without fluidity) around the via hole cannot be squeezed into the via hole to form the adhesive overflow. A long board fabrication way of bonding the short copper-clad laminate (single copper layer) onto the bare circuit board or copper foil to obtain a double-layer circuit board used before is abandoned, the defect of adhesive overflow caused by the conventional long board fabrication way is completely overcome. The long circuit board fabricated in this way features a firmly bonded copper plating layer at the via hole position, which is not easy to loosen or detach. In addition, the front copper layer and the back copper layer can form a good and reliable conduction at the via hole position. With reference to FIG. 6A and FIG. 6B, the adhesive overflow cannot be produced at the via hole 4 position, the copper plating layer b can be well bonded to a hole wall of the via hole 4, thereby achieving good conduction between the front copper layer 11 and the back copper layer 12. With reference to FIG. 7, in the long circuit board fabricated in the prior art, there is obvious overflowed adhesive a in the via hole, the surface of the overflowed adhesive a is uneven, which causes the copper plating layer (b) bonded to the overflowed adhesive to be poorly adhered during subsequent copper electroplating, resulting in voids and gaps. This ultimately affects the reliable conduction between the front copper layer and the back copper layer.

In a third aspect, an embodiment of the present disclosure provides an electronic product, including the long circuit board according to any of the foregoing embodiments, where an electronic component is soldered to the long circuit board, and the electronic product is a mobile phone, a vehicle, a computer, a robot, or an LED light strip.

The embodiments of the present disclosure have been described in detail above with reference to the accompanying drawings, but the present disclosure is not limited to the above embodiments, and various changes can be made within the knowledge of those of ordinary skill in the art without departing from the purpose of the present disclosure.

1. A fabrication method for a long circuit board, comprising the following steps:
material preparation: preparing a long copper-clad laminate, wherein the long copper-clad laminate comprises a front copper layer and a back copper layer on an upper surface and a lower surface of the long copper-clad laminate, and an intermediate insulating layer is disposed between the front copper layer and the back copper layer;
adhesive application: applying adhesive at intervals on the long copper-clad laminate to form a plurality of adhesive positions arranged at intervals in a length direction of the long copper-clad laminate;
laminate cutting: cutting the long copper-clad laminate into a plurality of short copper-clad laminates, wherein the short copper-clad laminate comprises Board A with adhesive on both ends, Board A with adhesive on both ends and Board B without adhesive on both ends, or Board C with adhesive on one end;
hole making: stacking the plurality of short copper-clad laminates and drilling to form via holes on the short copper-clad laminates, wherein each via hole penetrates through the front copper layer, the back copper layer and the intermediate insulating layer;
laminating joining: overlapping m short copper-clad laminates with pre-drilled holes end to end, wherein overlapping positions are bonded together with the adhesive at ends;
via hole electroplating; and
circuit fabricating.

2. The fabrication method for a long circuit board according to claim 1, wherein in the laminate cutting process, cutting is carried out on the adhesive position to obtain Board A with adhesive on both ends; or, in the laminate cutting process, cutting is carried out outside of the adhesive position to obtain Board A with adhesive on both ends and Board B without adhesive on both ends; or, in the laminate cutting process, cutting is simultaneously carried out on the adhesive position and a long copper-clad laminate between adjacent adhesive positions to obtain Board C with adhesive on one end.

3. The fabrication method for a long circuit board according to claim 1, wherein the method further comprises a copper removal process, which comprises partially removing sandwiched copper at the overlapping position to form a toothed end, and bonding overlapping positions of the ends together by the adhesive at the toothed ends; or further comprises a copper removal process, which comprises completely removing sandwiched copper at the overlapping position, and bonding two intermediate insulating layers together at the overlapping positions of ends by adhesive; or further comprises a copper removal process, which comprises partially removing sandwiched copper at the overlapping position, wherein only one sandwiched copper layer is at the overlapping position.

4. The fabrication method for a long circuit board according to claim 3, wherein before adhesive application, the copper removal process is implemented on the long copper-clad laminate; or after adhesive application and before laminate cutting, the copper removal process is implemented; after laminate cutting and before hole making, the copper removal process is implemented at one end or both ends of the short copper-clad laminate; or after hole making and before laminating joining, the copper removal process is implemented at one end or both ends of the short copper-clad laminate, or after laminating joining, the copper removal process is implemented at the overlapping position.

5. The fabrication method for a long circuit board according to claim 1, wherein the long copper-clad laminate is longer than 3 meters, and the short copper-clad laminate is shorter than or equal to 3 meters.

6. A fabrication method for a long circuit board, comprising the following steps:
material preparation: preparing m short copper-clad laminates, wherein each short copper-clad laminate comprises a front copper layer and a back copper layer on an upper surface and a lower surface thereof, and an intermediate insulating layer is disposed between the front copper layer and the back copper layer;
hole making: stacking the plurality of short copper-clad laminates and drilling to form via holes on the short copper-clad laminates, wherein each via hole penetrates through the front copper layer, the back copper layer and the intermediate insulating layer;
adhesive application: applying adhesive to both ends of all short copper-clad laminates to obtain Board A; or, applying adhesive to both ends of a part of the short copper-clad laminates to obtain Board A, and enabling the other short copper-clad laminates without adhesive applied to both ends to form Board B.; or, applying adhesive to one end of the short copper-clad laminate to obtain Board C;
laminating joining: overlapping m short copper-clad laminates with pre-drilled holes end to end, wherein overlapping positions are bonded together with the adhesive at ends;
via hole electroplating; and
circuit fabricating.

7. The fabrication method for a long circuit board according to claim 6, wherein the method further comprises a copper removal process, which comprises partially removing sandwiched copper at the overlapping position to form a toothed end, and bonding overlapping positions of the ends together by the adhesive at the toothed ends; or further comprises a copper removal process, which comprises completely removing sandwiched copper at the overlapping position, and bonding two intermediate insulating layers together at the overlapping positions of ends by adhesive; or further comprises a copper removal process, which comprises partially removing sandwiched copper at the overlapping position, wherein only one sandwiched copper layer is at the overlapping position.

8. The fabrication method for a long circuit board according to claim 7, wherein before hole making, the copper removal process is implemented at one end or both ends of the short copper-clad laminate; or after hole making and before glue application, the copper removal process is implemented at one end or both ends of the short copper-clad laminate; or after glue application, the copper removal process is implemented at one end or both ends of the short copper-clad laminate; or after laminating joining, the copper removal process is implemented at the overlapping position.

9. The fabrication method for a long circuit board according to claim 4, wherein the copper removal process is as follows: simultaneously cutting away a copper layer as well as an intermediate insulating layer at a tooth slot position by using a die or milling cutter to obtain a fully hollowed-out tooth slot; or, removing unnecessary copper from the front copper layer or/and the back copper layer of the copper-clad laminate by using a milling cutter or laser, retaining the intermediate insulating layer at a tooth slot position to obtain a semi hollowed-out tooth slot; or, coating an anti-etching material on the copper-clad laminate to expose a position on the copper-clad laminate where the copper layer needs to be removed, and then placing the copper-clad laminate coated with the anti-etching material into an etching solution to etch and remove the front copper layer or/and the back copper layer of the copper-clad laminate which is not covered by the anti-etching material, and retaining an intermediate insulating layer at the tooth slot position to obtain a semi hollowed-out tooth slot; or, removing the copper at the end of the front copper layer or/and the back copper layer, making the end of a front side or/and a back side free of copper.

10. The fabrication method for the long circuit board according to claim 1, wherein the adhesive application refers to adhesive printing, adhesive pasting, or adhesive dispensing.

11. The fabrication method for the long circuit board according to claim 1, wherein the circuit board fabrication comprises photoresist application, exposure, development, and circuit etching.

12. The fabrication method for the long circuit board according to claim 1, wherein the copper-clad laminate is a double-layer board, or a multi-layer board, where an inner circuit layer is sandwiched between intermediate insulating layers, and the inner circuit layer is fabricated before drilling.

13. The fabrication method for the long circuit board according to claim 1, wherein after circuit fabrication, the method further comprises fabricating a solder mask.

14. A long circuit board, wherein the long circuit board is formed by overlapping and lapping m short circuit boards end to end, the short circuit board comprises a front circuit layer, a back circuit layer, and an intermediate insulating layer therebetween; the short circuit board is provided with a plurality of via holes, and each via hole penetrates through the front circuit layer, the back circuit layer, and the intermediate insulating layer; the short circuit board is a double-layer circuit board or a multi-layer circuit board, and adjacent short circuit boards are bonded together at an overlapping position, with at least two sandwiched copper layers at the overlapping position, which comprise a first copper layer on one short circuit board and a second copper layer on the adjacent short circuit board; or adjacent short circuit boards are bonded together at the overlapping position, with only one sandwiched copper layer at the overlapping position, wherein the copper layer is located on one of the short circuit board, and the adjacent short circuit board is bonded with the copper layer at the overlapping position through the intermediate insulating layer; or no copper layer is sandwiched in the overlapping position, and the two intermediate insulating layers are the overlapping position are bonded together.

15. The long circuit board according to claim 14, wherein the two short circuit boards are in conduction with each other, either through sidewall copper, and/or through solder.

16. The long circuit board according to claim 14, wherein when the first copper layer and/or the second copper layer is disposed at the overlapping position, the first copper layer and/or the second copper layer have/has a toothed end, the toothed end comprises tooth protrusions and tooth slots, wherein the tooth protrusions form tooth protrusion circuits, part or all of the tooth protrusion circuits are connected to a circuit at a non-overlapping position, and part or all of the tooth slots disconnect adjacent circuits; or, at the overlapping position, the first copper layer and the second copper layer are not toothed.

17. The long circuit board according to claim 16, wherein at the tooth slot position, the first copper layer and/or the second copper layer are/is toothed, and the intermediate insulating layer at the tooth slot position is retained; or the first copper layer and the second copper layer are toothed, and only one intermediate insulating layer is retained at the tooth slot position; or at the tooth slot position, the intermediate insulating layer and all copper layers form tooth slots.

18. The long circuit board according to claim 17, wherein at the overlapping position, a length of the overlapping position is less than that of the tooth protrusion.

19. The long circuit board according to claim 14, further comprising a solder mask, wherein the solder mask covers the tooth slot; or the solder mask does not cover the tooth slot.

20. The long circuit board according to claim 14, wherein when the first copper layer and the second copper layer are disposed on the overlapping position, the first copper layer and the second copper layer are not connected to the circuit at the non-overlapping position, or at least one wire extends from the first copper layer and the second copper layer to connect the circuit at the non-overlapping position.

21. (canceled)

22. (canceled)

23. (canceled)
